(19) United States
(12) Patent Application Publication
(10) Pub. No.: US 2024/0312952 A1
(43) Pub. Date: Sep. 19, 2024

(54) Bonding Semiconductor Dies Through Wafer Bonding Processes

(71) Applicant: Taiwan Semiconductor Manufacturing Co., Ltd., Hsinchu (TW)

(72) Inventors: Yung-Chi Lin, Su-Lin City (TW); Ming-Tsu Chung, Hsinchu (TW)

(21) Appl. No.: 18/326,316

(22) Filed: May 31, 2023

Related U.S. Application Data
(60) Provisional application No. 63/490,840, filed on Mar. 17, 2023.

(51) Int. Cl. H01L 23/00; H01L 21/78; H01L 23/48

(52) U.S. Cl. CPC H01L 24/80; H01L 21/78; H01L 23/481; H01L 24/08; H01L 24/94; H01L 2224/08145; H01L 2224/80895; H01L 2224/80896; H01L 2224/94

(57) ABSTRACT

A method comprises bonding a first wafer with a second wafer through wafer-on-wafer bonding, wherein the second wafer includes a first plurality of device dies therein. A second plurality of device dies are bonded on the second wafer through chip-on-wafer bonding. A gap-filling process is performed to fill the gaps between the second plurality of device dies with gap-filling regions. The gap-filling regions and the second plurality of device dies collectively form a reconstructed wafer.

### PRIORITY CLAIM AND CROSS-REFERENCE

This application claims the benefit of the following provisionally filed U.S. Patent Application No. 63/490,840, filed on Mar. 17, 2023, and entitled “Bonding process Flow for Semiconductor Device Including Stacked Semiconductor Dies,” which application is hereby incorporated herein by reference.

### BACKGROUND

With the increasingly greater integration level of integrated circuits, semiconductor devices, instead of having all integrated circuits formed in the same die, having more and more device dies bonded together to form packages, wherein the device dies having different functions may work together to achieve system functions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-18 illustrate the intermediate stages in a wafer bonding process and the formation of a package in accordance with some embodiments.

FIGS. 19-23 illustrate the packages formed in accordance with some embodiments.

FIG. 24 illustrates a top view of a reconstructed wafer in accordance with some embodiments.

FIG. 25 illustrates a process flow for forming a package based on wafer-on-wafer bonding in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A multi-die stack and the method of forming the same are provided. In accordance with some embodiments, a device wafer is bonded to a first carrier through wafer-on-wafer bonding. The device wafer is then thinned from backside, and backside redistribution lines are formed on the wafer. Device dies are then bonded on the wafer through chip-on-wafer bonding to form a reconstructed wafer. A bevel filling process is performed to fill the corners on the reconstructed wafer. A carrier switch process is preformed, and electrical connectors may be formed on the front side of the wafer. The wafer is then sawed. Through the wafer-on-wafer bonding process, the manufacturing cost may be reduced. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

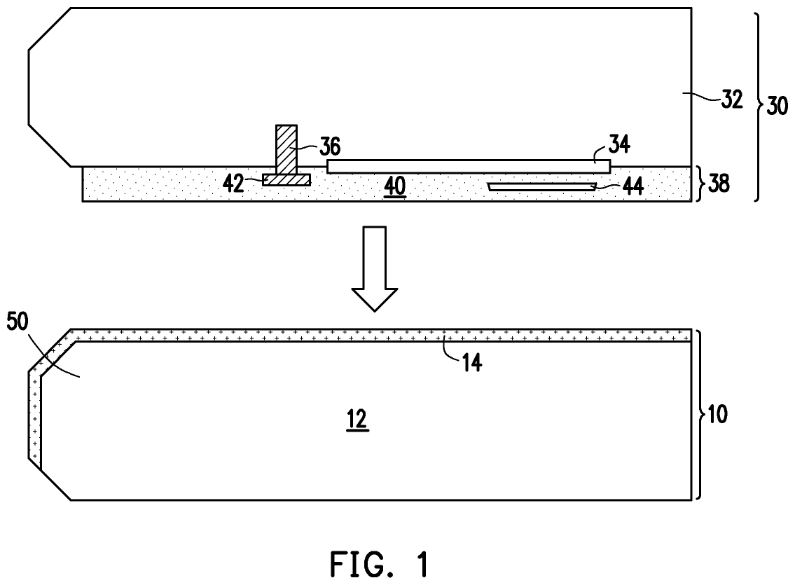

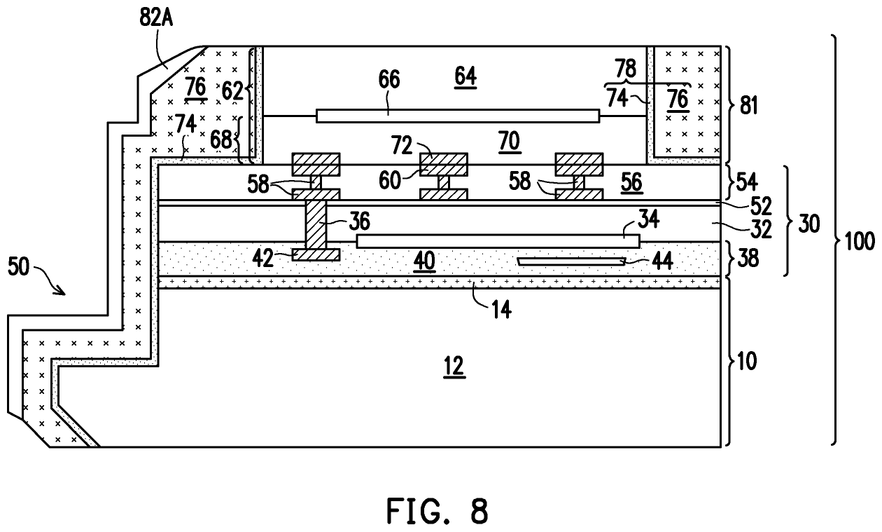

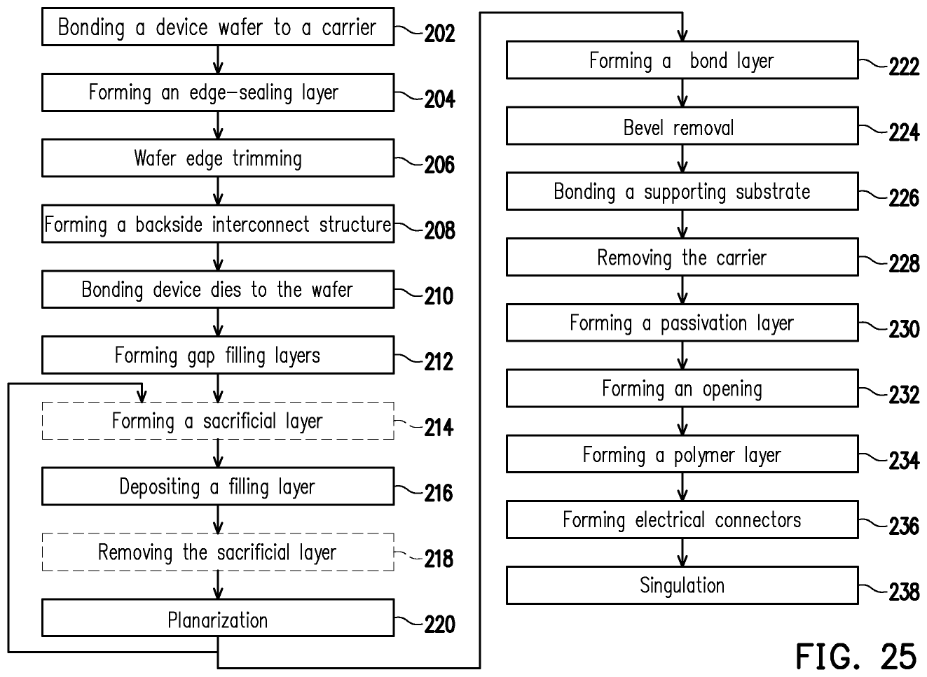

FIGS. 1-18 illustrate the cross-sectional views of intermediate stages in the formation of a package through wafer-on-wafer bonding in accordance with some embodiments. The corresponding processes are also reflected schematically in the process flow 200 as shown in FIG. 25.

Referring to FIG. 1, wafer 10 is formed. In accordance with some embodiments, wafer 10 is a carrier that has no active devices (such as transistors) and passive devices therein, and hence is referred to as carrier 10 hereinafter. Carrier 10 may have a round top view shape, with FIG. 1 illustrating a corner part of wafer 10. In accordance with some embodiments, carrier 10 includes substrate 12. Substrate 12 may be a blank substrate, and may be formed of a same material as the substrate 32 in device wafer 30, so that in the subsequent packaging process, the warpage due to the mismatch in Coefficients of Thermal Expansion (CTE) values between carrier 10 and device wafer 30 is reduced. Substrate 12 may be formed of or comprise silicon, while other materials such as ceramic, glass, silicate glass, or the like may also be used. In accordance with some embodiments, the entire substrate 12 is formed of a homogeneous material, with no other material different from the homogeneous material therein. For example, the entire substrate 12 may be formed of silicon (doped or undoped), and there is no metal region, dielectric region, etc., therein.

In accordance with alternative embodiments, wafer 10 is a device wafer including active devices (such as transistors) and/or passive devices (such as capacitors, resistors, inductors, and/or the like) therein. Wafer 10, when being the device wafer, may be an un-sawed wafer including a semiconductor substrate continuously extending into all device dies in the wafer, or may be a reconstructed wafer including discrete device dies that are packaged in an encapsulant (such as a molding compound or inorganic gap-filling regions).

Bond layer 14 is deposited on substrate 12. In accordance with some embodiments, bond layer 14 is formed of or comprises a dielectric material, which may be a silicon-based dielectric material such as silicon oxide (SiO₂), SiN, SiON, SiOCN, SiC, SiCN, or the like, or combinations thereof. In accordance with some embodiments, bond layer 14 is formed using High-Density Plasma Chemical Vapor Deposition (HDPCVD), Plasma Enhanced Chemical Vapor Deposition (PECVD), Chemical Vapor Deposition (CVD), Low-Pressure Chemical Vapor Deposition (LPCVD), Atomic Layer deposition (ALD), or the like.

In accordance with some embodiments, bond layer 14 is in physical contact with substrate 12. In accordance with alternative embodiments, carrier 10 includes a plurality of layers (not shown) between bond layer 14 and substrate 12. For example, there may be an oxide-based layer formed of an oxide-based material (which may also be silicon oxide based) such as silicon oxide, phospho-silicate glass (PSG), borosilicate glass (BSG), boron-doped phospho silicate glass (BPSG), fluorine-doped silicate glass (FSG), or the like. There may also be a nitride-based layer formed of or comprising silicon nitride, silicon oxynitride (SiON), or the like. In accordance with some embodiments, the layers between substrate 12 and bond layer 14 may be formed using PECVD, CVD, LPCVD, ALD, or the like. There may also be alignment marks (not shown) formed between bond layer 14 and substrate 12. The alignment marks may be formed as metal plugs, which may be formed through damascene processes.

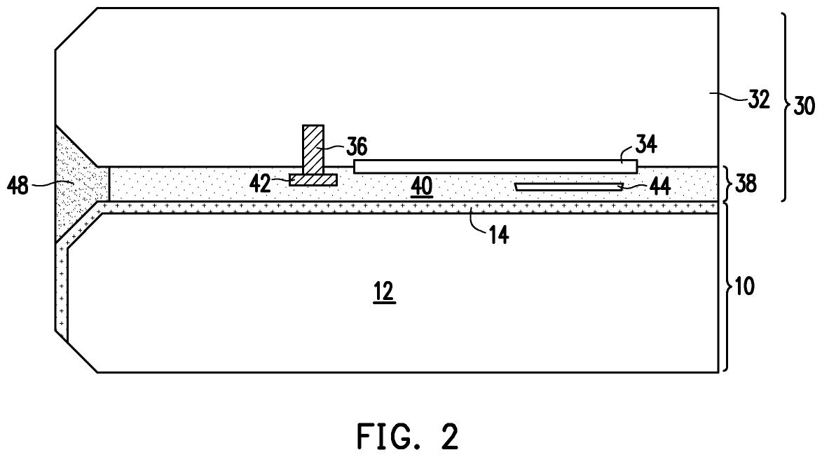

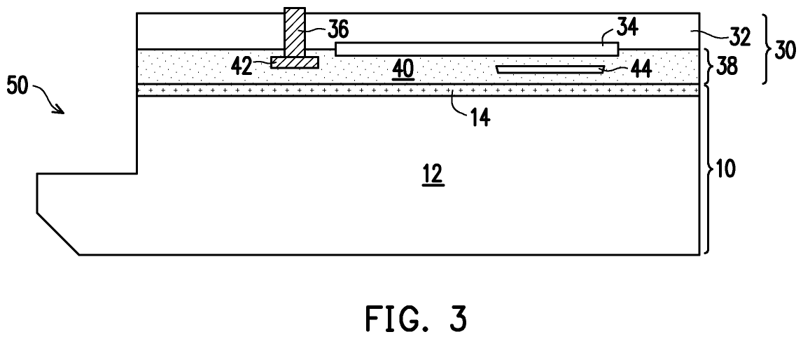

Device wafer 30 is also formed. Device wafer 30 may be an un-sawed wafer, and the bonding process as shown in FIG. 2 is a wafer-on-wafer bonding process. In accordance with some embodiments, device wafer 30 includes substrate 32, and integrated circuit devices 34 at a surface of substrate 32. In accordance with some embodiments, through-substrate vias 36 are formed extending from the front side (the illustrated bottom side) into substrate 32. In accordance with alternative embodiments, no through-vias are formed at this stage, and the through-vias are formed in the process as shown in FIG. 3. Substrate 32 may be a semiconductor substrate such as a silicon substrate. In accordance with other embodiments, substrate 32 may include other semiconductor materials such as silicon germanium, carbon-doped silicon, or the like. Substrate 32 may be a bulk substrate, or may have a layered structure, for example, including a silicon substrate and a silicon germanium layer over the silicon substrate.

In accordance with some embodiments, device wafer 30 includes device dies, which may include logic dies, memory dies, input-output dies, Integrated Passive Devices (IPDs), or the like, or combinations thereof. For example, the logic device dies in device wafer 30 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in device wafer 30 may include Static Random-Access Memory (SRAM) dies, Dynamic Random-Access Memory (DRAM) dies, or the like. Device wafer 30 may be a simple device wafer including a semiconductor substrate extending continuously throughout device wafer 30, or may be a reconstructed wafer including device dies packaged therein, which device dies may be integrated as a system.

In accordance with some embodiments, integrated circuit devices 34 are formed on the front surface (the illustrated bottom surface) of semiconductor substrate 32. Example integrated circuit devices 34 may include Complementary Metal-Oxide Semiconductor (CMOS) transistors, resistors, capacitors, diodes, and/or the like. The details of integrated circuit devices 34 are not illustrated herein. In accordance with alternative embodiments, device wafer 30 is used for forming interposers, in which substrate 32 may be a semiconductor substrate or a dielectric substrate.

Front-side interconnect structure 38 is formed on the front side of substrate 32. The front-side interconnect structure 38 may include a plurality of dielectric layers 40 such as an Inter-Layer Dielectric (ILD), Inter-Metal Dielectrics (IMDs), non-low-k passivation layers, polymer layers, and/or the like. In accordance with some example embodiments, the ILD is formed of or comprises silicon oxide, PSG, BSG, BPSG, FSG, or the like. The IMD layers may be formed of low-k dielectric materials having dielectric constant values (k-values) lower than about 3.0. For example, the IMD layers may comprise a carbon-containing low-k dielectric material(s), Hydrogen SilsesQuioxane (HSQ), MethylSilsesQuioxane (MSQ), or the like.

The front-side interconnect structure 38 further includes conductive features in the dielectric layers. The conductive features may include contact plugs, metal lines, and metal pads, (schematically illustrated as 42), metal vias, and/or the like. The contact plugs may be formed of tungsten, aluminum, copper, titanium, tantalum, titanium nitride, tantalum nitride, alloys therefore, and/or multi-layers thereof. Each of the metal lines and the metal vias may include a diffusion barrier layer and a copper-containing metallic material on the diffusion barrier layer. The diffusion barrier layer may include titanium, titanium nitride, tantalum, tantalum nitride, or the like.

In accordance with some embodiments, there may be metal pads 44 formed in dielectric layers 40. The metal pads 44 may be formed of or comprise aluminum, copper, nickel, titanium, palladium, or the like, or alloys thereof. In accordance with some embodiments, metal pads 44 are in a passivation layer. In accordance with alternative embodiments, a polymer layer (which may be polyimide, polybenzoxazole (PBO), or the like) may be formed, with the metal pads 44 being in the polymer layer.

Device wafer 30 is bonded to carrier 10 through wafer-on-wafer bonding. The respective process is illustrated as process 202 in the process flow 200 as shown in FIG. 25. The resulting structure is shown in FIG. 2. A surface dielectric layer in dielectric layers 40 is bonded to bond layer 14 through fusion bonding, with Si—O—Si bonds being formed to join the surface dielectric layer in dielectric layers 40 to bond layer 14.

Further referring to FIG. 2, edge-sealing layer 48 is dispensed into the edge gap between substrate 12 and substrate 32, and on the sidewalls of interconnect structure 38. The respective process is illustrated as process 204 in the process flow 200 as shown in FIG. 25. In accordance with some embodiments, edge-sealing layer 48 is formed of or comprises a polymer, which may be polyimide, PBO, or the like. Edge-sealing layer 48 may be dispensed in a flowable form, and is then cured and solidified. Furthermore, edge-sealing layer 48 is dispensed as a ring fully encircling interconnect structure 38.

Referring to FIG. 3, a wafer edge trimming process is performed to form recess 50, which forms a recess ring along the peripheral of wafers 10 and 30. The respective process is illustrated as process 206 in the process flow 200 as shown in FIG. 25. A backside grinding process is then performed from the backside of device wafer 30, and substrate 32 is thinned. The backside grinding process may be performed through a Chemical Mechanical Polish (CMP) process or a mechanical polishing process. In the backside grinding process, edge-sealing layer 48 has the function of preventing device wafer 30 from peeling off from carrier 10. The backside grinding process is performed until through-vias 36 are exposed.

In accordance with some embodiments, after through-vias 36 are exposed, semiconductor substrate 32 is slightly recessed, for example, through an etching process, so that the top portions of through-vias 36 protrude out of the recessed semiconductor substrate 32.

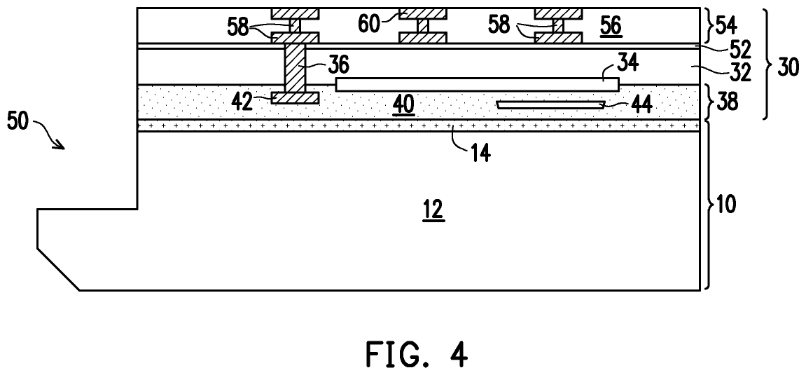

Next, as shown in FIG. 4, dielectric isolation layer 52 is formed to embed the protruding portions of through-vias 36 therein. In accordance with some embodiments, dielectric isolation layer 52 is first formed by depositing a dielectric material, which may be formed of or comprise silicon oxide, silicon nitride, or the like. A planarization process is then performed to remove the excess portions of the dielectric material over through-vias 36, so that through-vias 36 are revealed again. The remaining dielectric material is dielectric isolation layer 52.

Further referring to FIG. 4, backside interconnect structure 54 is formed. The respective process is illustrated as process 208 in the process flow 200 as shown in FIG. 25. Backside interconnect structure 54 includes one or a plurality of dielectric layers 56 and one or a plurality of layers of redistribution lines (RDLs) 58. In accordance with some embodiments, RDLs 58 are formed through damascene processes, which include depositing the corresponding dielectric layers 56, forming trenches and via openings in the dielectric layers 56, and filling the trenches and the via openings with a metallic material(s) to form RDLs 58. Dielectric layers 56 may be formed of or comprise inorganic dielectric materials such as silicon oxide, silicon nitride, silicon oxynitride, or the like. In accordance with alternative embodiments, dielectric layers 56 may be formed of polymers, which may be photo-sensitive, and the formation process of an RDLs 58 may include depositing a metal seed layer, forming and patterning a plating mask over the metal seed layer, performing a plating process to form the RDLs, removing the plating mask to expose the underlying portions of the metal seed layer, and etching the exposed portions of the metal seed layer.

In accordance with some embodiments, bond pads 60 are formed as the surface conductive features of wafer 30. Bond pads 60 may have top surfaces coplanar with the top surface of a top dielectric layer in dielectric layers 56. In accordance with some embodiments, bond pads 60 are formed of or comprise copper. The top dielectric layer in dielectric layers 56 may be formed of or comprise a silicon-containing dielectric material such as silicon oxide, silicon nitride, SiC, SiOC, SiON, SiOC, or the like.

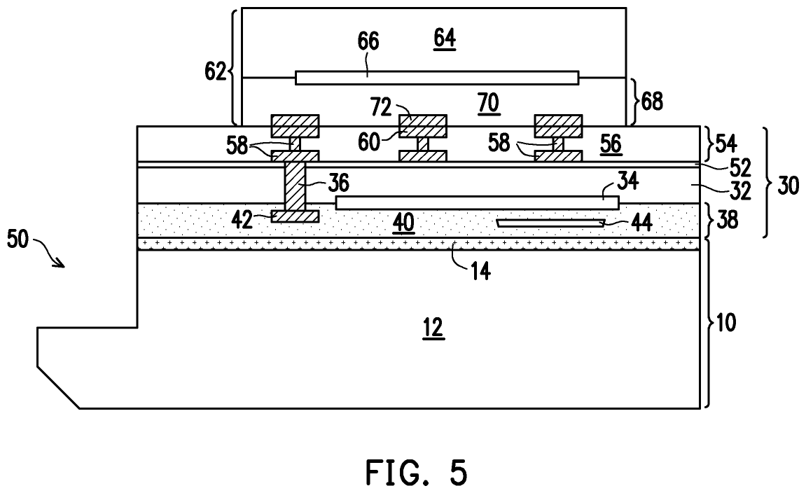

Referring to FIG. 5, a plurality of device dies 62 are bonded to wafer 30 through chip-on-wafer bonding. The respective process is illustrated as process 210 in the process flow 200 as shown in FIG. 25. The bonding may be achieved through face-to-back bonding, with the front side of device dies 62 being bonded to the backside of the dies in wafer 30. Each die in wafer 30 may be bonded with one or more of device dies 62. Each die 62 may also be bonded with one or more dies in wafer 30. Device dies 62 may include semiconductor substrates 64, and integrated circuits 66 at the surface of semiconductor substrates 64. Semiconductor substrates 64 may be a silicon substrate.

Each device die 62 may include interconnect structure 68, which includes dielectric layers 70 and conductive features (not shown) therein. Bond pads 72 are formed as the surface conductive features of device dies 62. Bond pads 72 may have surfaces (the illustrated bottom surfaces) coplanar with the surface of a surface dielectric layer in dielectric layers 70. In accordance with some embodiments, bond pads 72 are formed of or comprise copper. The surface dielectric layer in dielectric layers 70 may be formed of or comprise a silicon-containing dielectric material such as silicon oxide, silicon nitride, SiC, SiOC, SiON, SiOC, or the like.

The bonding may be achieved through hybrid bonding. For example, bond pads 72 are bonded to bond pads 60 through metal-to-metal direct bonding. In accordance with some embodiments, the metal-to-metal direct bonding is copper-to-copper direct bonding. Furthermore, the surface dielectric layer in dielectric layers 70 is bonded to the surface dielectric layer in dielectric layers 56 through fusion bonding, for example, with Si—O—Si bonds generated.

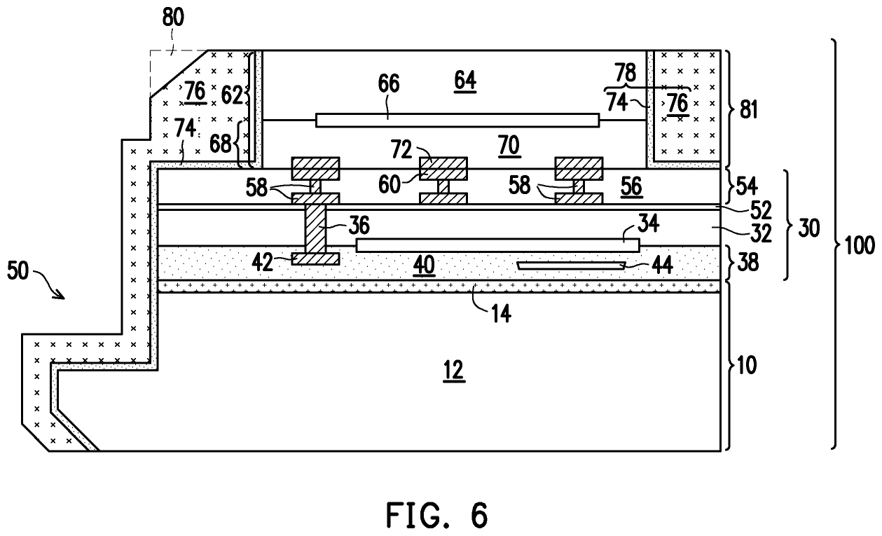

FIG. 6 illustrates a gap-filling process for forming gap-filling layers/regions. The respective process is illustrated as process 212 in the process flow 200 as shown in FIG. 25. In accordance with some embodiments, the gap-filling layers includes adhesion layer 74, and dielectric layer 76 over and contacting adhesion layer 74. Adhesion layer 74 may be deposited using a conformal deposition process such as Atomic Layer Deposition (ALD) or Chemical Vapor Deposition (CVD). Accordingly, adhesion layer 74 may be a conformal layer, for example, with the thickness of the horizontal portions and the thickness of the vertical portions being substantially equal to each other (for example, with a variation smaller than about 20 percent). Adhesion layer 74 is formed of a dielectric material that has good adhesion to the sidewalls of device dies 62 and the top surface of dielectric layer 56. In accordance with some embodiments, adhesion layer 74 is formed of or comprises a nitride-containing material such as silicon nitride.

Dielectric layer 76 is formed of a material different from the material of adhesion layer 74. In accordance with some embodiments, dielectric layer 76 is formed of or comprises silicon oxide, while other dielectric materials such as silicon carbide, silicon oxynitride, silicon oxy-carbo-nitride, or the like may also be used. Dielectric layer 76 may be a non-conformal layer with the thicknesses of the horizontal portions and vertical portions being different from each other, or may be a conformal layer.

Further referring to FIG. 6, a planarization process such as a CMP process or a mechanical grinding process is performed to remove excess portions of the gap-filling layers 74 and 76, so that the top surface of substrates 64 are exposed. Substrates 64 may also be polished to a desirable thickness, for example, smaller than about 50 μm. The remaining portions of layers 74 and 76 are collectively referred to as gap-filling regions 78. Throughout the description, the structure shown in FIG. 6 is referred to as reconstructed wafer 100.

Device dies 62 and the gap-filling regions 78 are collectively referred to as reconstructed wafer 81. In accordance with alternative embodiments, instead of bonding device dies 62 to wafer 30 and forming reconstructed wafer 81 based on the bonded device dies 62, the reconstructed wafer 81 may be pre-formed, and then bonded to the underlying wafer through wafer-on-wafer bonding. Similarly, wafer 30 may be an unsawed device wafer, or may be a reconstructed wafer having a similar structure as reconstructed wafer 81. The reconstructed wafer is bonded to carrier 10 through wafer-on-wafer bonding.

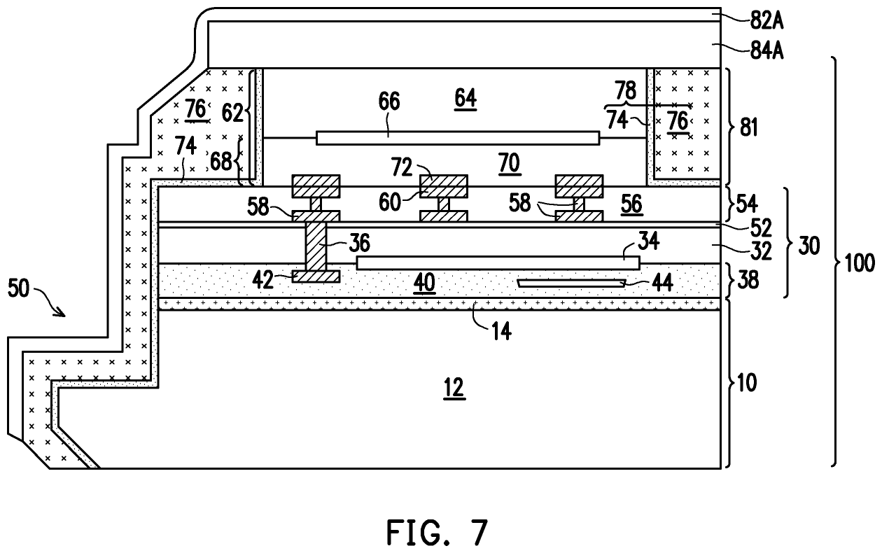

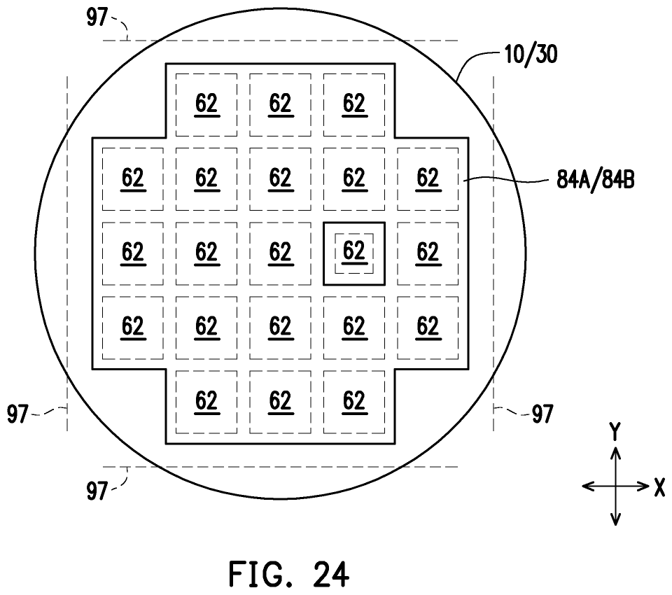

Gap-filling regions 78 have chamfers, and hence have bevel recesses 80, which laterally extend to the sidewalls of the trimmed wafer 30. The bevel recesses 80 may adversely affect the subsequent processes such as the bonding of a supporting substrate. For example, as shown in FIG. 24, since device dies 62 may be positioned as an array, and the top view of wafer 30 is rounded, some device dies 62 may be farther away from the wafer edges than other device dies 62, resulting in large and wide bevel recesses 80. Accordingly, bevel recesses 80 may be filled before the subsequent processes. FIGS. 7 through 10 illustrate some example processes for filling the bevel recesses with bevel-recess filling regions 82 in accordance with some embodiments.

Referring to FIG. 7, a sacrificial layer 84 is formed Sacrificial layer 84A may be formed to cover the regions of reconstructed wafer 100 where device dies are distributed, but not some regions between the outmost ones of device dies 62 and the respective closest edges of reconstructed wafer 100. The respective process is illustrated as process 214 in the process flow 200 as shown in FIG. 25. Sacrificial layer 84A may comprise a photoresist.

FIG. 24 illustrates an example top view of sacrificial layer 84A, which may cover all of the device dies 62, and having edges vertically aligned to the outer edges of the outmost device dies 62, or expand slightly beyond the outer edges of the outmost device dies 62. Due to that the bevel recesses may be larger where the outmost edges of the outmost device dies 62 are farther away from the edges of the wafer 30 than where they are closer to the edges of wafer 20, sacrificial layer 84A may have the edges close to device dies 62. In accordance with some embodiments, in the top view of the reconstructed wafer 100, sacrificial layer 84A may be formed as having a non-circular shape (although wafer 30 has a circular top-view shape).

Referring again to FIG. 7, a first filling layer 82A is deposited. The respective process is illustrated as process 216 in the process flow 200 as shown in FIG. 25. The first filling layer 82A may comprise or may be formed of silicon oxide, silicon oxynitride, silicon oxycarbide, silicon oxy-carbo-nitride, or the like, or combinations thereof. The material of the first filling layer 82A may be the same as or different from the material of dielectric layer 76.

In accordance with alternative embodiments, sacrificial layer 84 is not formed, and the first filling layer 82A is in contact with semiconductor substrate directly. Processes 214 and 218 illustrated in the process flow 200 in FIG. 25 are thus shown as being dashed to indicate that these processes may be, or may not be, performed.

In accordance with some embodiments, the deposition of the first filling layer 82A may adopt a non-conformal deposition process such as PVD or PECVD, so that the top portions of the first filling layer 82A are thicker than the sidewall portions. The non-conformal first filling layer 82A is more efficient in filling the bevel recesses. Alternatively, the first filling layer 82A may be formed of a conformal deposition process such as CVD. Some portions of first filling layer 82A are deposited on Sacrificial layer 84A.

After the deposition process, sacrificial layer 84A is removed, for example, in an etching process. The respective process is illustrated as process 218 in the process flow 200 as shown in FIG. 25. The portions of the first filling layer 82A on top of sacrificial layer 84A are thus removed, which is also referred to as being lifted. A first planarization process such as a CMP process may then be performed to level the top surface of the deposited first filling layer 82A with the top surface of device dies 62. The respective process is illustrated as process 220 in the process flow 200 as shown in FIG. 25. The preceding process including forming the sacrificial layer 84A, depositing the first filling layer 82A, removing the sacrificial layer 84A, and the planarization process are collectively referred to a first bevel-filling cycle.

In accordance with alternative embodiments, the first bevel-filling cycle includes the deposition of the first filling layer 82A and the subsequent planarization process, and does not include the deposition and the removal of the sacrificial layer 84A. In accordance with yet alternative embodiments, the first bevel-filling cycle includes deposition the sacrificial layer 84A, depositing the first filling layer 82A, removing the sacrificial layer 84A, and does not include the subsequent planarization process. The planarization process is performed after all subsequent bevel-filling cycles have been finished.

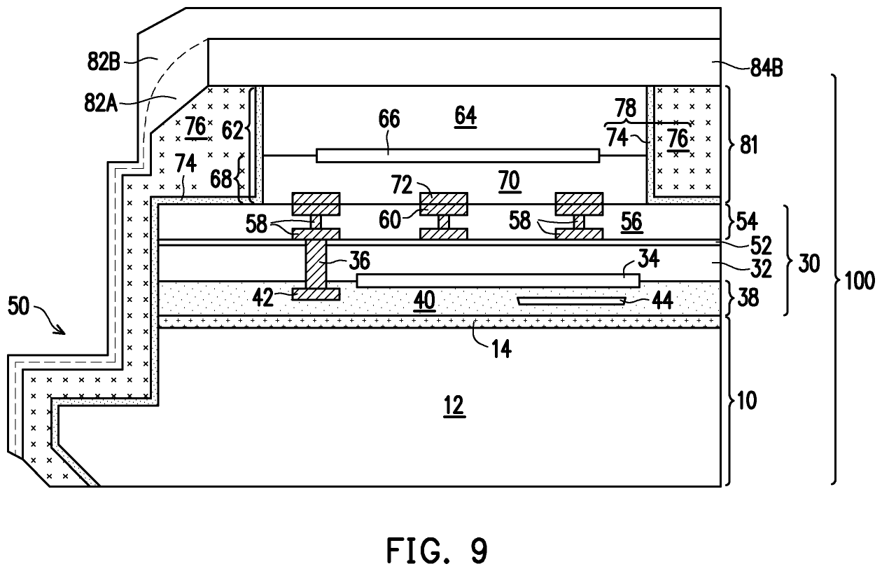

In accordance with some embodiments in which the bevel-recesses are not fully filled, after the first bevel-filling cycle, a second bevel-filling cycle may be performed. The respective process is shown in FIG. 25 as looping back to process 214. For example, FIG. 9 illustrates an intermediate stage in the second bevel-filling cycle, which includes forming and patterning sacrificial layer 84B, depositing a second filling layer 82B, removing the sacrificial layer 84B to lift some portions of the second filling layer 82B, and possibly performing a second planarization process. The second filling layer 82B may comprise or may be formed of silicon oxide, silicon oxynitride, silicon oxycarbide, silicon oxy-carbo-nitride, or the like, or combinations thereof. Also, the material of the second filling layer 82B may be the same as or different from the material of the first filling layer 82A.

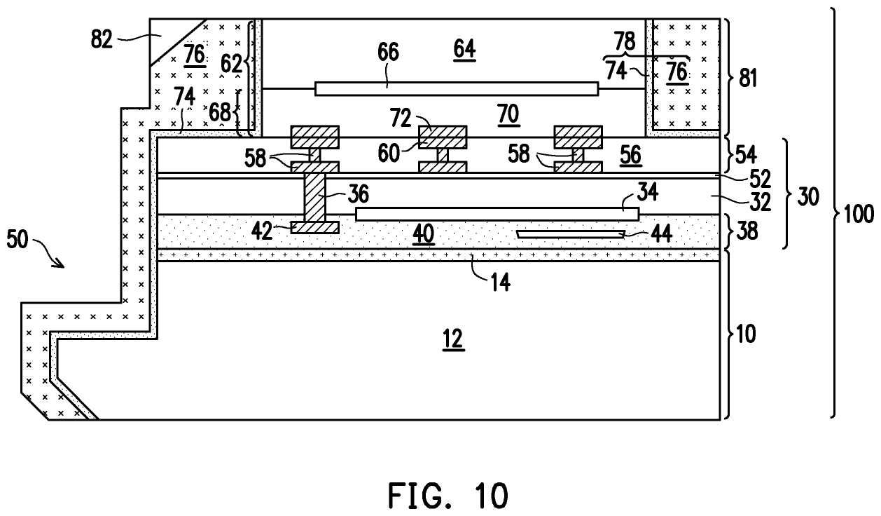

The bevel-filling cycles may be repeated until the bevel recesses are fully filled or substantially fully filled, for example, with more than 90 percent of the volume filled. The remaining portions of the filling layers (including second filling layers 82A and 82B or more if more bevel-filling cycles are included) are collectively referred to as bevel-filling layers/regions 82. FIG. 10 illustrates a structure after a planarization process is performed. The planarization process may be in the last bevel-filling cycle, or may be a planarization process after the plurality of bevel-filling cycles if the bevel-filling cycles do not include planarization processes. As a result of the planarization process(es), the top surfaces of the substrates 64 in device dies 62 may be revealed, and are coplanar with the top surfaces of bevel-filling regions 82 and dielectric layer 76.

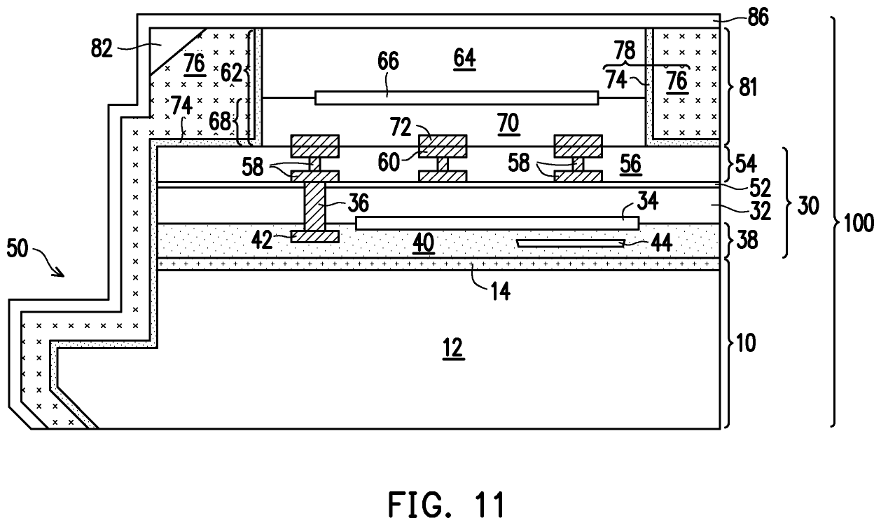

FIG. 11 illustrates the formation of bond layer 86. The respective process is illustrated as process 222 in the process flow 200 as shown in FIG. 25. In accordance with some embodiments, bond layer 86 comprises a silicon-containing dielectric material such as silicon oxide, silicon nitride, silicon carbide, SiOC, SiON, SiOCN, or combinations thereof. The formation process may be a conformal deposition process such as ALD, CVD, or the like.

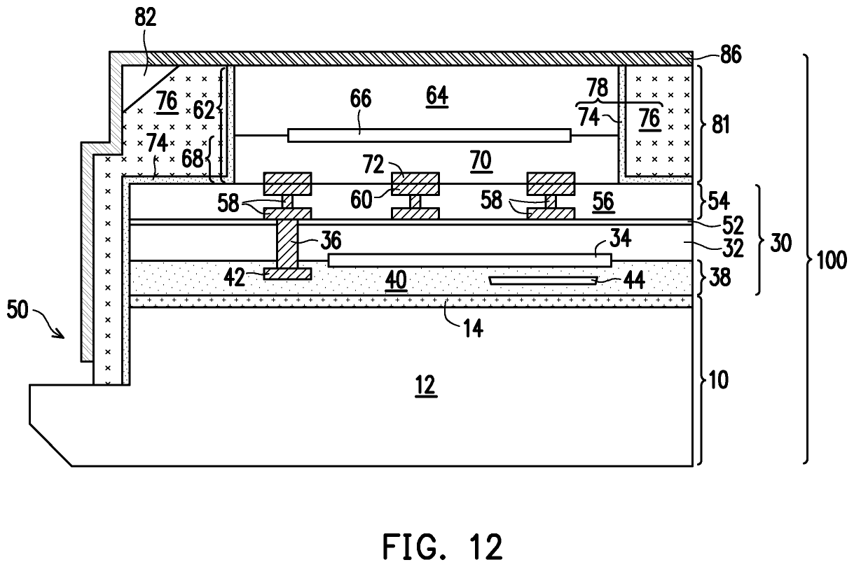

FIG. 12 illustrates a bevel removal process, in which some previously deposited materials are removed through etching. The respective process is illustrated as process 224 in the process flow 200 as shown in FIG. 25. The bevel removal process may reduce the chipping and the particles of these materials during the subsequent processes. In accordance with some embodiments, a photoresist (not shown) may be formed to cover the middle portions of the reconstructed wafer 100 as shown in FIG. 11. An etching process(es) may then be performed to remove the portions of bond layer 86 and dielectric layer 76 at the bottom corners of carrier 10.

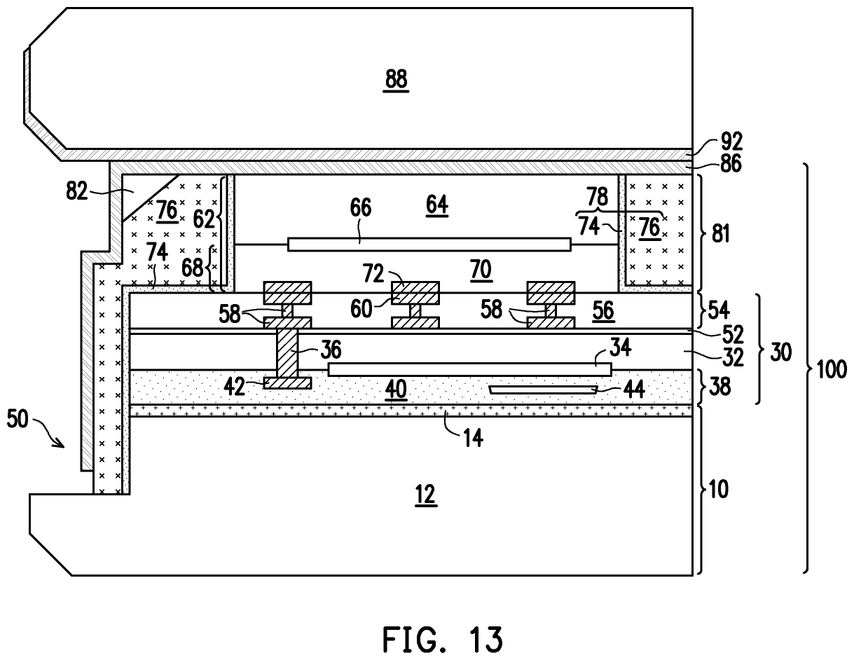

FIG. 13 illustrates the bonding of supporting substrate 88 to reconstructed wafer 100 in accordance with some embodiments. The respective process is illustrated as process 226 in the process flow 200 as shown in FIG. 25. Supporting substrate 88 is in wafer form, and hence is also referred to as a supporting wafer. Supporting substrate 88 may be bonded to bond layer 86 through bond layer 92. In accordance with some embodiments, bond layer 92 is pre-formed on supporting substrate 88, for example, through a thermal oxidation process or a deposition process, and the structure including both of bond layer 92 and supporting substrate 88 are bonded to bond layer 86.

Bond layer 92 may be a silicon-containing dielectric layer formed of or comprising SiO₂, SiN, SiC, SiON, or the like. The deposition process may include LPCVD, PECVD, PVD, ALD, PEALD, or the like. Supporting substrate 88 may be formed of a material that has a high thermal conductivity. In accordance with some embodiments, supporting substrate 88 is a silicon substrate, while another type of substrate such as another semiconductor substrate, a dielectric substrate, a metallic substrate, or the like may be used. The entire supporting substrate 88 may be formed of a homogenous material. For example, supporting substrate 88 may be free from active and passive devices, metal lines, dielectric layers, and the like therein. The bonding of bond layer 92 to bond layer 86 may include fusion bonding.

In accordance with some embodiments, after the bonding process, supporting substrate 88 is thinned, for example, in a mechanical grinding process or a CMP process, so that the thickness of supporting substrate 88 is reduced to a proper value. Supporting substrate 88 is thus thick enough to support the subsequent grinding of wafer 120 (FIG. 12), and is not too thick. In accordance with alternative embodiments, supporting substrate 88 is not thinned.

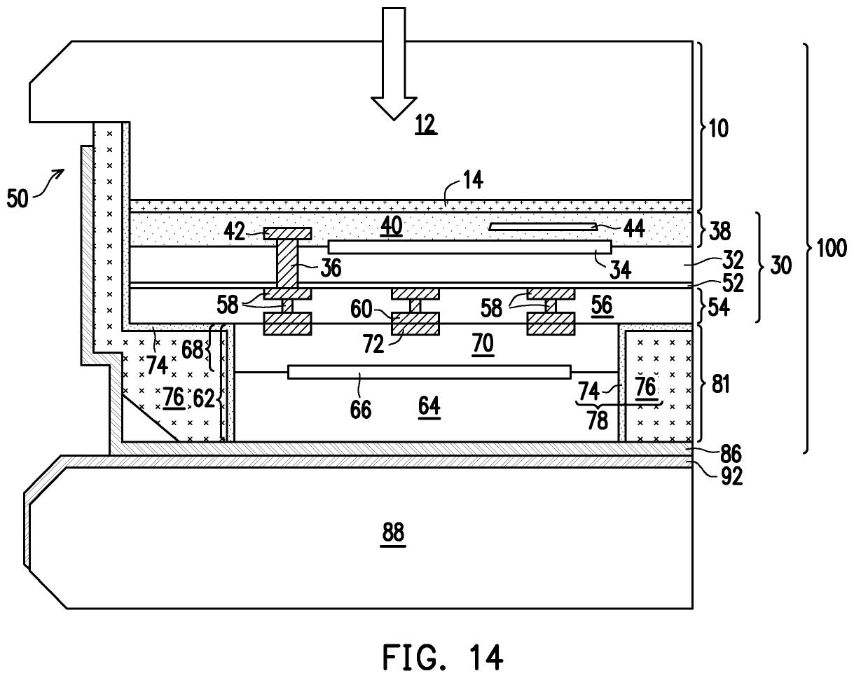

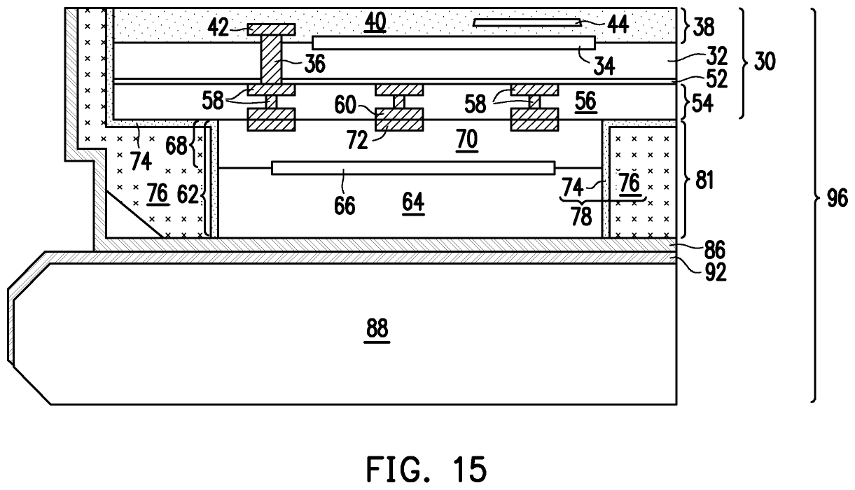

Reconstructed wafer 100 is then flipped upside down, as shown in FIG. 14. Next, carrier 10 is removed, for example, through a mechanical grinding process. The respective process is illustrated as process 228 in the process flow 200 as shown in FIG. 25. The carrier-removal process may be performed until wafer 30 is exposed, as shown in FIG. 15. The resulting structure is shown in FIG. 15, and is referred to as reconstructed wafer 96.

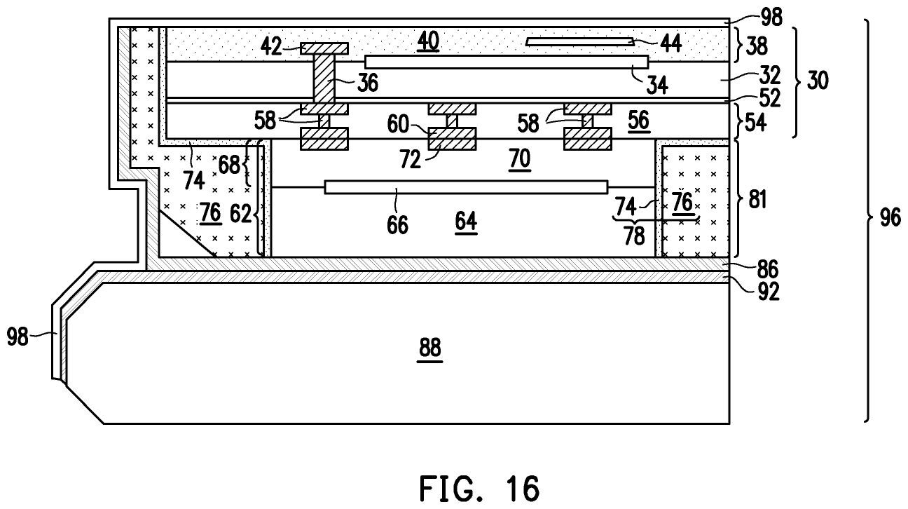

Referring to FIG. 16, passivation layer 98 is deposited. The respective process is illustrated as process 230 in the process flow 200 as shown in FIG. 25. Passivation layer 98 may be formed of a non-low-k dielectric layer, which has the function of blocking moisture. In accordance with some embodiments, passivation layer 98 is formed of or comprises silicon oxide, silicon nitride, USG, or the like, combinations thereof, or multi-layers thereof. Passivation layer 98 may be conformal, and may be formed using ALD, CVD, or the like.

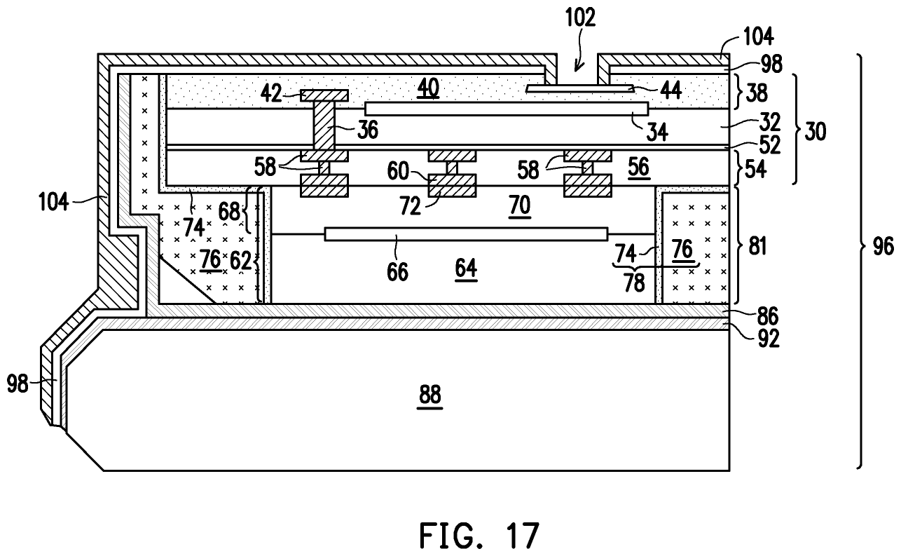

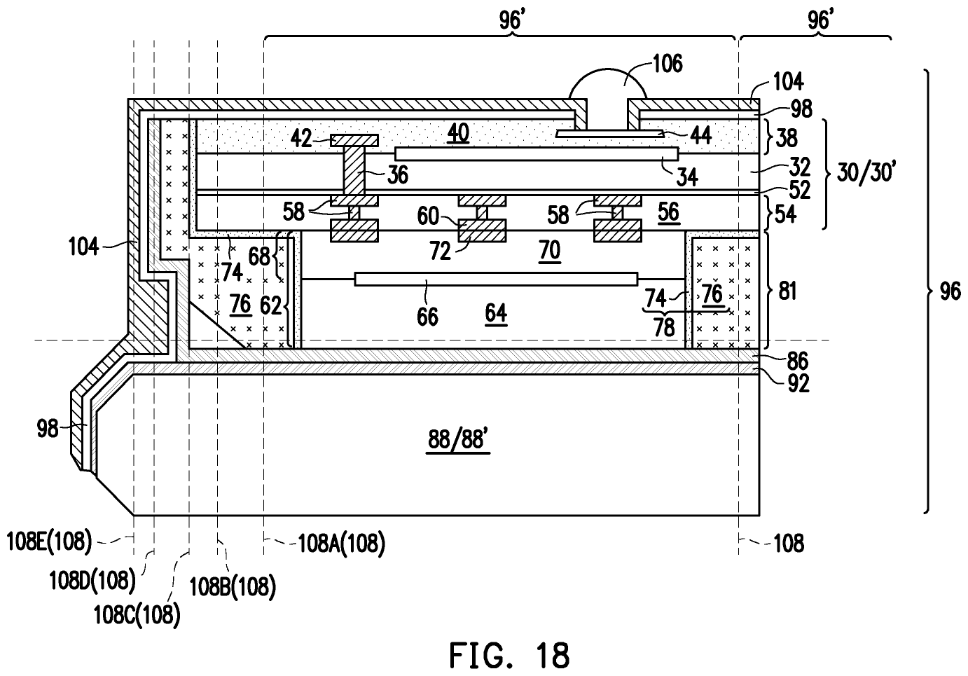

FIG. 17 illustrates the formation of opening 102, which is formed by etching passivation layer 98 and dielectric layer 40. The respective process is illustrated as process 232 in the process flow 200 as shown in FIG. 25. Polymer layer 104 may then be formed, and may extend into opening 102. The respective process is illustrated as process 234 in the process flow 200 as shown in FIG. 25. Metal pads 44 are exposed by removing the portion of the polymer layer 104 directly over metal pads 44. Next, as shown in FIG. 18, electrical connectors 106 are formed to electrically connect to metal pads 44. The respective process is illustrated as process 236 in the process flow 200 as shown in FIG. 25. Electrical connectors 106 may be solder regions, metal pillars, metal pads, or the like.

Reconstructed wafer 96 may be used in wafer form, wherein the entire wafer 96 is used as a package. Alternatively stated, reconstructed wafer 96 is used (powered up) in the final product. This may be used in performance-demanding applications such as Artificial Intelligence (AI) application. In accordance with these embodiments, reconstructed wafer 96 may or may not be trimmed to remove some edge portions that don't include device dies, circuits, routing lines, etc. For example, FIG. 24 schematically illustrates trimming lines 97 when reconstructed wafer 96 is trimmed, wherein the portions of the reconstrued wafer 96 outside of the trimming lines 97 are removed.

Referring to FIG. 18, in accordance with alternative embodiments, a singulation process is performed to saw reconstructed wafer 96 into discrete packages 96′, which are identical to each other. The respective process is illustrated as process 238 in the process flow 200 as shown in FIG. 25. In packages 96′, device dies 30′, which are parts of the sawed wafer 30, are referred to as tier-1 (T1) dies since they are the first to be bonded in the package formation process. Device dies 62 are referred to as tier-2 (T2) dies. The packages 96′ may also include supporting substrates 88′, which are pieces sawed from the wafer-level supporting substrate 88.

The singulation process may be performed along scribe lines 108. Scribe lines 108A, 108B, 108C, 108D, and 108E illustrate some possible positions of the singulation or trimming lines (which are shown as 97 in FIG. 24). Some of the packages 96′ at the edges of reconstructed wafer 96 may have unique structures. For example, when scribe line 108A is adopted, the respective package 96′ is free from the bevel-filling regions 82. Also, the edges of semiconductor substrate 32 are exposed. Otherwise, when scribe line 108B is adopted, the respective package 96′ may include bevel-filling regions 82, which is on the illustrated left side, but not on the illustrated right side, of package 96′. When scribe line 108C, 108D, or 108E is adopted, the respective package 96′ may further include adhesion layer 74 on the illustrated left side, but not on the illustrated right side, of package 96′. The scribe line may also be at any position between the positions of scribe line 108A and 108E.

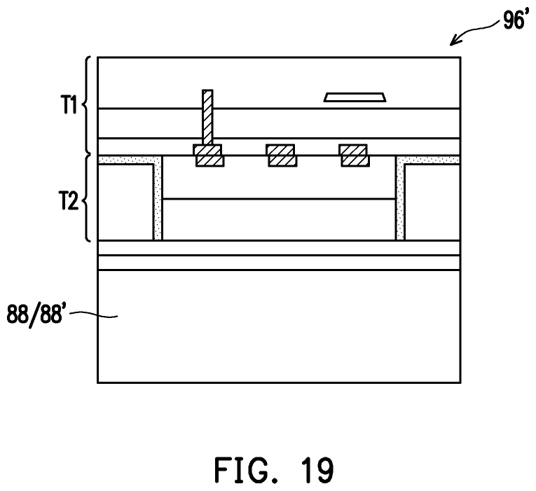

FIGS. 19 through 23 illustrate some packages 96′ formed in accordance with the embodiments of the present disclosure. The formation of these packages includes wafer-on-wafer bonding processes, wherein the wafers may include unsawed device wafers, or the reconstructed wafers that include discrete device dies encapsulated in encapsulants (gap-filling regions). In these packages, unless specified otherwise, the device dies marked as T1 are the device dies that are bonded (to initial carrier 10) before the bonding of T2 dies, and the device dies T2 are the device dies that are bonded to T1 dies before the bonding of T3 dies. The electrical connectors 106 are not shown in FIGS. 19-23, although they may exist.

FIG. 19 schematically illustrates a two-tier package 96′ same as the package 96′ as shown in FIG. 18, with some details omitted. The formation of the package includes a wafer-on-wafer bonding process, in which a device wafer including T1 dies is bonded to a carrier, followed by a chip-on-wafer bonding process, in which discrete T2 dies are bonded to the device wafer including the T1 dies through wafer-on-wafer bonding.

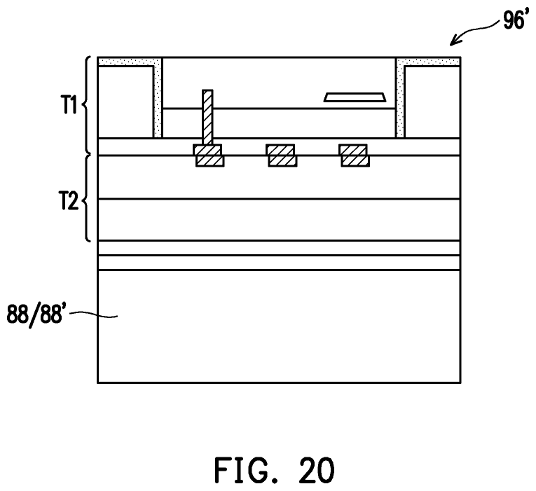

FIG. 20 schematically illustrates a two-tier package 96′. The formation of the package includes a chip-on-wafer bonding process, in which discrete T1 dies are bonded to a carrier wafer, followed by a gap-filling process to form a reconstructed wafer. A wafer-on-wafer bonding process may then be performed, in which an unsawed device wafer including T2 dies is bonded to the reconstructed wafer including the T1 dies. Supporting substrate 88 may then be bonded, and the carrier may be removed. A singulation process may be, or may not be, performed.

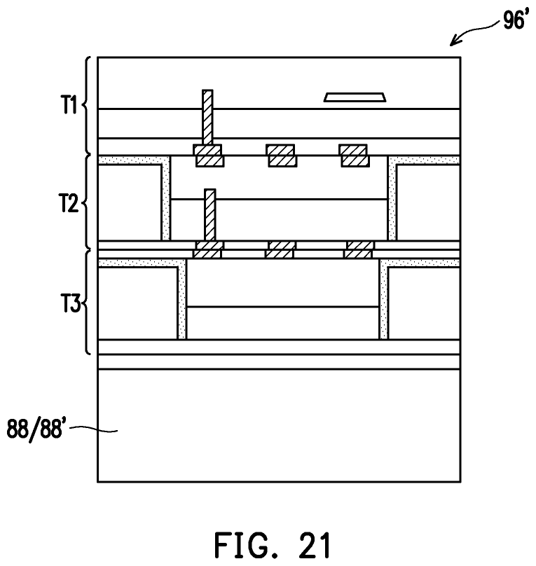

FIG. 21 schematically illustrates a three-tier package 96′. The formation of the package includes a chip-on-wafer bonding process, in which a device wafer including T1 dies is bonded to a carrier, followed by a chip-on-wafer bonding process, in which discrete T2 dies are bonded to the device wafer including the T1 dies. The T2 dies are encapsulated (gap-filled) to form a first reconstructed wafer. A second reconstructed wafer including the encapsulated T3 dies are then bonded to the first reconstructed wafer through wafer-on-wafer bonding. Alternatively, the T3 dies may be bonded to the T2 dies through chip-on-wafer bonding. A singulation process may be, or may not be, performed.

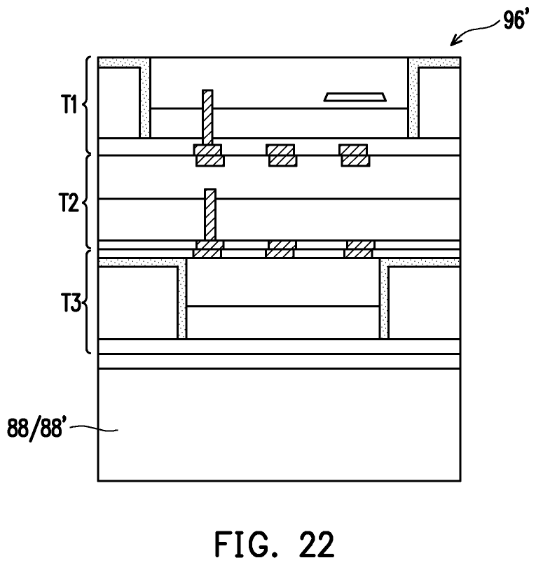

FIG. 22 schematically illustrates a three-tier package 96′. The formation of the package includes a chip-on-wafer bonding process, in which discrete T1 dies are bonded to a carrier to form a first reconstructed wafer, followed by a wafer-on-wafer bonding process, in which a device wafer including T2 dies is bonded to the first reconstructed wafer to form a second reconstrued wafer. Discrete T3 dies are then bonded to the T2 dies in the second reconstructed wafer through chip-on-wafer bonding, followed by an encapsulation process to fill the gaps between the T3 dies. Alternatively, the T3 dies may be pre-packaged to form a reconstructed wafer, which is bonded to the T2 dies through wafer-on-wafer bonding. A singulation process may be, or may not be, performed.

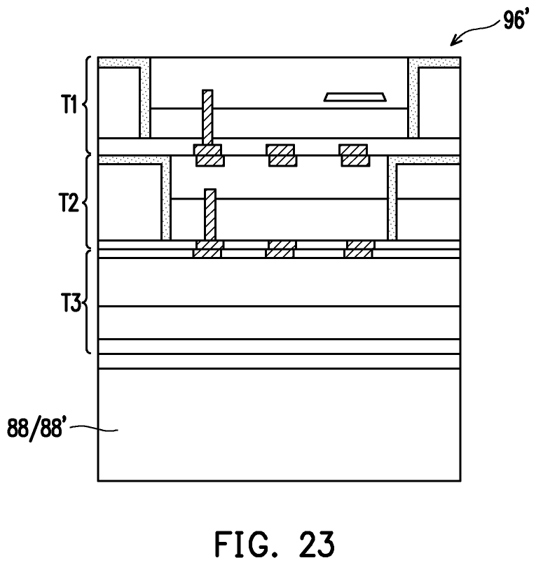

FIG. 23 schematically illustrates a three-tier package 96′. The formation of the package includes a chip-on-wafer bonding process, in which discrete T1 dies are bonded to a carrier to form a first reconstructed wafer, followed by a chip-on-wafer bonding process, in which discrete T2 dies are bonded to the first reconstructed wafer to form a second reconstrued wafer. Alternatively, the T2 dies may be pre-packaged to form a reconstructed wafer, which is bonded to the T1 dies through wafer-on-wafer bonding. A wafer including T3 dies is then bonded to the second reconstructed wafer through wafer-on-wafer bonding. A singulation process may be, or may not be, performed.

The embodiments of the present disclosure have some advantageous features. By performing wafer-on-wafer processes to form packages, the manufacturing cost is reduced since the preparation and the gap-filling process for the chips in the wafers may be saved. Combining the wafer-on-wafer process with chip-on-wafer bonding further provides more flexible in the manufacturing process of the integrated circuits.

In accordance with some embodiments, a method comprises bonding a first wafer with a second wafer through wafer-on-wafer bonding, wherein the second wafer comprises a first plurality of device dies therein; bonding a second plurality of device dies on the second wafer through chip-on-wafer bonding; and performing a gap-filling process to fill gaps between the second plurality of device dies with gap-filling regions, wherein the gap-filling regions and the second plurality of device dies collectively form a reconstructed wafer.

In an embodiment, the first wafer comprises a carrier, and the method further comprises bonding a supporting substrate on the second plurality of device dies through wafer-on-wafer bonding, wherein the supporting substrate and the first wafer are on opposing sides of the second wafer; and removing the first wafer. In an embodiment, the removing the first wafer comprises a grinding process. In an embodiment, the method further comprises, after the first wafer is removed, etching a dielectric layer in the second wafer to form an opening, with a metal pad in the second wafer being exposed; and forming an electrical connector on the metal pad.

In an embodiment, the method further comprises, after the gap-filling process, performing a bevel-filling process to fill bevel recesses that are close to edge regions of the reconstructed wafer. In an embodiment, the bevel-filling process comprises a plurality of cycles, and wherein each of the plurality of cycles comprises depositing a filling layer; and planarizing the filling layer. In an embodiment, each of the plurality of cycles further comprises forming a sacrificial layer covering a center portion of the reconstructed wafer, with edge portions of the reconstructed wafer being exposed, and a portion of the filling layer is deposited on the sacrificial layer; and after the filling layer is deposited, removing the sacrificial layer, with the portion of the filling layer being removed.

In an embodiment, the second wafer comprises a semiconductor substrate, and through-vias extending into the semiconductor substrate, and wherein the method further comprises before the second plurality of device dies are bonded on the second wafer, thinning the semiconductor substrate to reveal the through-vias. In an embodiment, the method further comprises sawing the reconstructed wafer to form a plurality of packages. In an embodiment, the method further comprises trimming edge portions of the reconstructed wafer to remove portions of the reconstructed wafer, with the trimmed portions being free from circuits. In an embodiment, the method further comprises, before the second plurality of device dies are bonded on the second wafer, performing an edge trimming process to remove an edge portion of the second wafer.

In accordance with some embodiments, a comprises bonding a device wafer to a carrier through fusion bonding, wherein the device wafer comprises integrated circuits therein; bonding a plurality of device dies on the device wafer through chip-on-wafer bonding; performing a gap-filling process to fill gaps between the plurality of device dies with gap-filling regions; bonding a supporting substrate to the gap-filling regions and the plurality of device dies; removing the carrier from the device wafer; and forming electrical connectors on the device wafer, wherein the electrical connectors are electrically connected to the integrated circuits in the device wafer.

In an embodiment, the supporting substrate comprises a blank silicon substrate. In an embodiment, the method further comprises, after the gap-filling process and before the supporting substrate is bonded to the gap-filling regions depositing a bond layer on the gap-filling regions and the plurality of device dies. In an embodiment, the method further comprises, before the supporting substrate is bonded, etching a portion of the gap-filling regions, wherein the etched portion being deposited on an edge of the carrier. In an embodiment, the method further comprises, before the plurality of device dies are bonded to the carrier, performing an edge trimming process to remove edge portions of the device wafer. In an embodiment, in the edge trimming process, an edge recess is formed to extend from a top surface of the carrier to an intermediate level between the top surface and a bottom surface of the carrier.

In accordance with some embodiments, a method comprises bonding a first plurality of device dies over a carrier through a first bonding process; bonding a second plurality of device dies over the first plurality of device dies through a second bonding process, wherein a first one of the first bonding process and the second bonding process comprises a wafer-on-wafer bonding process, and a second one of the first bonding process and the second bonding process comprises a chip-on-wafer bonding process; bonding a blanket silicon wafer over the second plurality of device dies; and removing the carrier. In an embodiment, the first plurality of device dies are in an un-sawed device wafer when the wafer-on-wafer bonding process is performed. In an embodiment, the first plurality of device dies are in a reconstructed wafer when the wafer-on-wafer bonding process is performed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
bonding a first wafer with a second wafer through wafer-on-wafer bonding, wherein the second wafer comprises a first plurality of device dies therein;
bonding a second plurality of device dies on the second wafer through chip-on-wafer bonding; and
performing a gap-filling process to fill gaps between the second plurality of device dies with gap-filling regions, wherein the gap-filling regions and the second plurality of device dies collectively form a reconstructed wafer.

2. The method of claim 1, wherein the first wafer comprises a carrier, and the method further comprises:
bonding a supporting substrate on the second plurality of device dies through wafer-on-wafer bonding, wherein the supporting substrate and the first wafer are on opposing sides of the second wafer; and
removing the first wafer.

3. The method of claim 2, wherein the removing the first wafer comprises a grinding process.

4. The method of claim 2 further comprising:
after the first wafer is removed, etching a dielectric layer in the second wafer to form an opening, with a metal pad in the second wafer being exposed; and
forming an electrical connector on the metal pad.

5. The method of claim 1 further comprising, after the gap-filling process, performing a bevel-filling process to fill bevel recesses that are close to edge regions of the reconstructed wafer.

6. The method of claim 5, wherein the bevel-filling process comprises a plurality of cycles, and wherein each of the plurality of cycles comprises:
depositing a filling layer; and
planarizing the filling layer.

7. The method of claim 6, wherein each of the plurality of cycles further comprises:
forming a sacrificial layer covering a center portion of the reconstructed wafer, with edge portions of the reconstructed wafer being exposed, and a portion of the filling layer is deposited on the sacrificial layer; and
after the filling layer is deposited, removing the sacrificial layer, with the portion of the filling layer being removed.

8. The method of claim 1, wherein the second wafer comprises a semiconductor substrate, and through-vias extending into the semiconductor substrate, and wherein the method further comprises:
before the second plurality of device dies are bonded on the second wafer, thinning the semiconductor substrate to reveal the through-vias.

9. The method of claim 1 further comprising sawing the reconstructed wafer to form a plurality of packages.

10. The method of claim 1 further comprising trimming edge portions of the reconstructed wafer to remove portions of the reconstructed wafer, with the trimmed portions being free from circuits.

11. The method of claim 1 further comprising, before the second plurality of device dies are bonded on the second wafer, performing an edge trimming process to remove an edge portion of the second wafer.

12. A method comprising:
bonding a device wafer to a carrier through fusion bonding, wherein the device wafer comprises integrated circuits therein;
bonding a plurality of device dies on the device wafer through chip-on-wafer bonding;
performing a gap-filling process to fill gaps between the plurality of device dies with gap-filling regions;
bonding a supporting substrate to the gap-filling regions and the plurality of device dies;
removing the carrier from the device wafer; and
forming electrical connectors on the device wafer, wherein the electrical connectors are electrically connected to the integrated circuits in the device wafer.

13. The method of claim 12, wherein the supporting substrate comprises a blank silicon substrate.

14. The method of claim 12 further comprising, after the gap-filling process and before the supporting substrate is bonded to the gap-filling regions:
depositing a bond layer on the gap-filling regions and the plurality of device dies.

15. The method of claim 12 further comprises, before the supporting substrate is bonded, etching a portion of the gap-filling regions, wherein the etched portion being deposited on an edge of the carrier.

16. The method of claim 12 further comprising:
before the plurality of device dies are bonded to the carrier, performing an edge trimming process to remove edge portions of the device wafer.

17. The method of claim 16, wherein in the edge trimming process, an edge recess is formed to extend from a top surface of the carrier to an intermediate level between the top surface and a bottom surface of the carrier.

18. A structure comprising:
a first device die;
a second device die underlying and bonding to the first device die, wherein the second device die comprises a semiconductor substrate;
a gap-filling region encircling the second device die;
a bevel-recess filling region on a side of, and contacting, the gap-filling region;
a bond layer contacting the bevel-recess filling region, the gap-filling region, and the semiconductor substrate; and
a supporting substrate bonding to the second device die through the bond layer, wherein an entirety of the supporting substrate is formed of a homogeneous material.

19. The structure of claim 18, wherein in a cross-sectional view of the structure, the bevel-recess filling region has a triangular shape.

20. The structure of claim 18 further comprising a dielectric layer contacting both of the bevel-recess filling region and the gap-filling region, wherein in a cross-sectional view of the structure, the dielectric layer is elongated and having a lengthwise direction perpendicular to an interface between the first device die and the second device die.
